(19) United States
(12) Patent Application Publication
(10) Pub. No.: US 2015/0369043 A1
(43) Pub. Date: Dec. 24, 2015

(54) FLUID ANALYSIS SYSTEM WITH INTEGRATED COMPUTATION ELEMENT FORMED USING ATOMIC LAYER DEPOSITION

(71) Applicant: HALLIBURTON ENERGY SERVICES, INC., Houston, TX (US)

(72) Inventors: Michael T. Pelletier, Houston, TX (US); David L. Perkins, The Woodlands, TX (US)

(73) Assignee: HALLIBURTON ENERGY SERVICES, INC., Houston, TX (US)

(21) Appl. No.: 14/766,960

(22) PCT Filed: Feb. 11, 2013
(86) PCT No.: PCT/US13/25546

§ 371 Date: Aug. 10, 2015

(51) Int. Cl. E21B 49/08; C23C 16/455; G01V 8/22; G01N 21/59; G01N 21/47

(52) U.S. Cl. CPC E21B 49/087; G01N 21/59; G01N 21/4738; G01V 8/22; C23C 16/45525; G01N 2201/068; G01N 2201/12

(57) ABSTRACT

Fluid analysis systems with Integrated Computation Elements (ICEs) or other optical path components formed using atomic layer deposition (ALD) enables improved tolerances and design flexibility. In some of the disclosed embodiments, a fluid analysis system includes a light source and an ICE. The fluid analysis system also includes a detector that converts optical signals to electrical signals. The ICE comprises a plurality of optical layers, where at least one of the plurality of optical layers is formed using ALD. A related method includes selecting an ICE design having a plurality of optical layers. The method also includes forming at least one of the plurality of optical layers of the ICE using ALD to enable prediction of a chemical or physical property of a substance. A related logging string includes a logging tool section and a fluid analysis tool associated with the logging tool section. The fluid analysis tool includes an ICE with at least one optical layer formed using ALD.

### BACKGROUND

Integrated Computation Elements (ICEs) have been used to perform optical analysis of fluids and material composition of complex samples. ICEs can be constructed by providing a series of layers having thicknesses and reflectivities designed to interfere constructively or destructively at desired wavelengths to provide an encoded pattern specifically for the purpose of interacting with light and providing an optical computational operation which allows for the prediction of a chemical or material property. The construction method for ICEs is similar to the construction method for an optical interference filter. For a complex waveform, an ICE constructed by conventional interference filter means may require a very large number of layers. In addition to being complicated to fabricate, such constructed ICEs may fail to perform optimally in harsh environments. For example, ICEs having a very large number of layers, or with individual layers that are thick relative to the film stack thickness, or with extremely tight tolerances, can have their prediction performance adversely affected by the temperature, shock, and vibration conditions in the downhole environment of a drilling setup for hydrocarbon exploration or extraction.

Efforts have been made to design and manufacture simplified ICEs that can provide complex spectral characteristics with a significantly reduced number of layers or layer thicknesses. However, many ICE designs (the recipe of layers and thicknesses to achieve a desired chemical prediction) are discarded due to the limitations and variance of available deposition techniques such as reactive magnetron sputtering (RMS).

### BRIEF DESCRIPTION OF THE DRAWINGS

Accordingly, there are disclosed herein fluid analysis systems with one or more optical path components formed or modified using atomic layer deposition (ALD). In the drawings:

FIG. 1 shows an illustrative fluid analysis system.

FIG. 2 shows illustrative layers of an ALD-based integrated computation element (ICE).

FIG. 3 shows a target transmission spectra and an intermediate model transmission spectra for an ALD-based ICE.

FIG. 4 shows an illustrative logging while drilling (LWD) environment.

FIG. 5 shows an illustrative wireline logging environment.

FIG. 6 shows an illustrative computer system for managing logging operations.

FIG. 7 shows a flowchart of an illustrative ICE fabrication method.

FIG. 8 shows a flowchart of an illustrative fluid analysis system fabrication method.

FIG. 9 shows a flowchart of an illustrative fluid analysis method.

The drawings show illustrative embodiments that will be described in detail. However, the description and accompanying drawings are not intended to limit the invention to the illustrative embodiments, but to the contrary, the intention is to disclose and protect all modifications, equivalents, and alternatives falling within the scope of the appended claims.

### NOMENCLATURE

Certain terms are used throughout the following description and claims to refer to particular system components. This document does not intend to distinguish between components that differ in name but not function. The terms “including” and “comprising” are used in an open-ended fashion, and thus should be interpreted to mean “including, but not limited to . . . ”.

The term “couple” or “couples” is intended to mean either an indirect or direct electrical, mechanical, or thermal connection. Thus, if a first device couples to a second device, that connection may be through a direct connection, or through an indirect connection via other devices and connections. Conversely, the term “connected” when unqualified should be interpreted to mean a direct connection. For an electrical connection, this term means that two elements are attached via an electrical path having essentially zero impedance.

### DETAILED DESCRIPTION

Disclosed herein are fluid analysis systems with one or more optical path components formed or modified using atomic layer deposition (ALD). Such optical path components may include, but are not limited to, an integrated computational element (ICE) (sometimes referred to as a multi variate optical element or MOE), a light source, a bandpass filter, a fluid sample interface, an input-side lens, an output-side lens, and a detector. As described herein, ALD may be utilized to fabricate or modify certain optical path component parts or layers, not necessarily entire components. Each layer formed using ALD may correspond to a planar (flat) or non-planar (curved or sloped) layer of an ICE or other optical path components.

Use of ALD improves fabrication consistency and tolerances for optical path components of a fluid analysis system compared to other fabrication options. Further, use of ALD may affect optical path component design criteria such as the number of layers, layer optical density, and layer thickness. Further, use of ALD may facilitate quality control operations during manufacture of optical path components. Further, use of ALD-based components enables improved fluid analysis system performance in harsh environments such as encountered in oil exploration and extraction drilling. The improved performance in harsh environments is due to the fabrication consistency and tolerances possible with ALD. Further, design criteria for optical path components that are avoided for other deposition techniques, such as reactive magnetron sputtering (RMS), are available with ALD. In some embodiments, RMS may be employed to fabricate some component layers, while ALD is employed to modify those layers and/or to fabricate other layers. The choice to employ RMS or ALD may depend on design tolerances (e.g., ALD may be employed when design tolerances are achievable using ALD, but not RMS). In an example fluid analysis application, an ICE formed using ALD may provide a multivariate prediction of a chemical or physical property of a substance. As disclosed herein, use of an ICE and/or other optical path components formed using ALD in a fluid analysis system may improve the accuracy, type, and/or range of predictions made by a fluid analysis system.

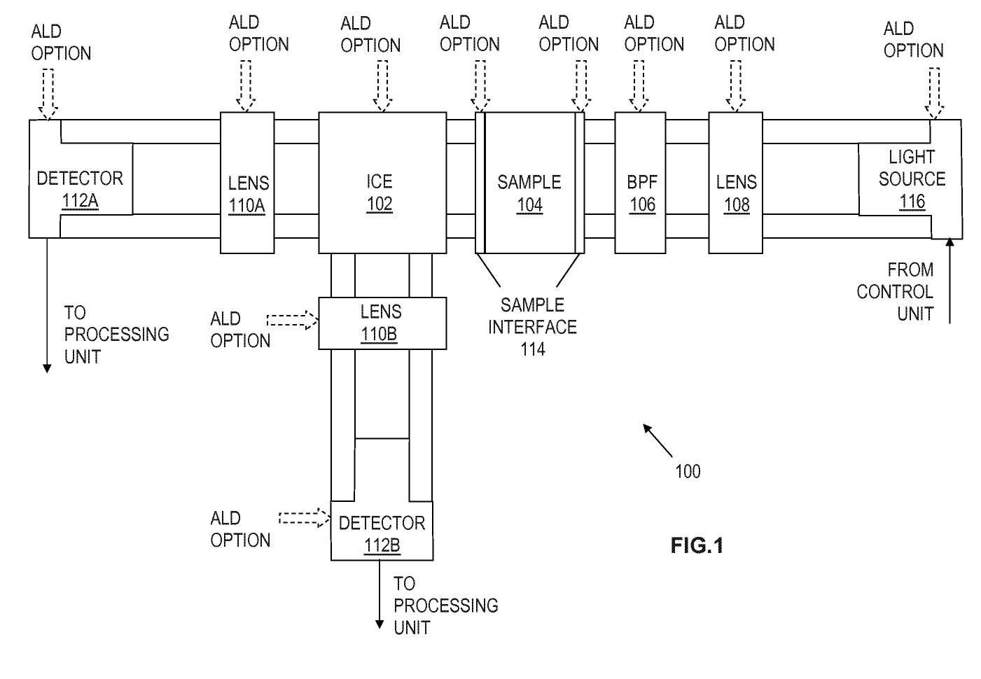

FIG. 1 shows an illustrative fluid analysis system 100. In fluid analysis system 100, various optical path components are shown including an ICE 102, a sample interface 114, a bandpass filter 106, an input-side lens 108, output-side lenses 110A and 110B, and detectors 112A and 112B. More specifically, ICE 102 is positioned between a light source 116 and detectors 112A and 112B. Additional or fewer detectors may be used. Further, a fluid sample 104 is positioned between the light source 116 and ICE 102. The position of the fluid sample 104 may be set using fluid sample interface 114, which holds the fluid sample in its place. Meanwhile, the input-side lens 108 and the output-side lenses 110A and 110B are configured to focus the direction of light. Further, a bandpass filter (BPF) 106 may be employed on an input-side of ICE 102 to filter certain wavelengths of light. Although FIG. 1 illustrates a suitable arrangement for the optical path components of fluid analysis system 100, it should be understood that other optical path component arrangements are possible. Further, additional optical path components such as lenses and/or reflectors may be employed.

As disclosed herein, one or more of the optical path components of fluid analysis system 100 may be fabricated or modified using ALD. For example, at least a portion of ICE 102 may be fabricated or modified using ALD. Further, at least some of light source 116, BPF 106, lens 108, lenses 110A and 110B, detectors 112A and 112B, and/or sample interface 104 may be fabricated or modified using ALD.

In operation, the fluid analysis system 100 is able to correlate certain characteristics of the fluid sample 104. The principles of operation of fluid analysis system 100 are described, in part, in Myrick, Soyemi, Schiza, Parr, Haibach, Greer, Li and Priore, “Application of multivariate optical computing to simple near-infrared point measurements,” Proceedings of SPIE vol. 4574 (2002).

In operation, light from light source 116 passes through lens 108, which may be a collimating lens. Light coming out of lens 108 has a specific wavelength component distribution, represented by a spectrum. Bandpass filter 106 transmits light from a pre-selected portion of the wavelength component distribution. Light from bandpass filter 106 is passed through sample 104, and then enters ICE 102. According to some embodiments, sample 104 may include a liquid having a plurality of chemical components dissolved in a solvent. For example, sample 104 may be a mixture of hydrocarbons including oil and natural gas dissolved in water. Sample 104 may also include particulates forming a colloidal suspension including fragments of solid materials of different sizes.

Sample 104 will generally interact with light that has passed bandpass filter 106 by absorbing different wavelength components to a varying degree and letting other wavelength components pass through. Thus, light output from sample 104 has a spectrum S(λ) containing information specific to the chemical components in sample 104. Spectrum S(λ) may be represented as a row vector having multiple numeric entries, Sᵢ. Each numeric entry Sᵢ is proportional to the spectral density of light at a specific wavelength λ. Thus, entries Sᵢ are all greater than or equal to zero (0). Furthermore, the detailed profile of spectrum S(λ) may provide information regarding the concentration of each chemical component within the plurality of chemicals in sample 140. Light from sample 104 is partially transmitted by ICE 102 to produce light measured by detector 112A after being focused by lens 110A. Another portion of light is partially reflected from ICE 102 and is measured by detector 112B after being focused by lens 110B. In some embodiments, ICE 102 may be an interference filter with certain spectral characteristic that can be expressed as row vector L(λ). Vector L(λ) is an array of numeric entries, Lᵢ, such that the spectra of transmitted light and reflected light is:

S_{LT}(λ)=S(λ)·(½+L(λ)), (1.1)

S_{LR}(λ)=S(λ)·(½−L(λ)), (1.2)

Note that the entries Lᵢ in vector L(λ) may be less than zero, zero, or greater than zero. Thus, while S(λ), S_{LT}(λ), and S_{LR}(λ) are spectral densities, L(λ) is a spectral characteristic of ICE 102. From Eqs. (1.1) and (1.2) it follows that:

S_{LT}(λ)−S_{LR}(λ)=2·S(λ)·L(λ), (2)

Vector L(λ) may be a regression vector obtained from the solution to a linear multivariate problem targeting a specific component having concentration K in sample 104. In such case, it follows that:

$$κ = β \cdot {\sum }_{λ} ( {S}_{LT} ( λ ) - {S}_{LR} ( λ ) ) + γ , \qquad ( 3 )$$

where β is a proportionality constant and γ is a calibration offset. The values of β and γ depend on design parameters of fluid analysis system 100 and not on sample 104. Thus, parameters β and γ may be measured independently of the field application of fluid analysis system 100. In at least some embodiments, ICE 102 is designed specifically to provide L(λ) satisfying Eqs. (2) and (3), above. By measuring the difference spectra between transmitted light and reflected light, the value of the concentration of the selected component in sample 104 may be obtained. Detectors 112A and 112B may be single area photo-detectors that provide an integrated value of the spectral density. That is, if the signal from detectors 112A and 112B is d₁ and d₂ respectively, Eq. (3) may be readjusted for a new calibration factor β′ as:

κ=β·(d₁−d₂)+γ, (4)

In some embodiments, fluid analysis systems such as system 100 may perform partial spectrum measurements that are combined to obtain the desired measurement. In such case, multiple ICEs may be used to test for a plurality of components in sample 104 that may be of interest. Regardless of the number of ICEs in system 100, each ICE may include an interference filter having a series of parallel layers 1 through K, each having a pre-selected index of refraction and a thickness. The number K may be any integer greater than zero. Thus, ICE 102 may have K layers, where at least one of the layers is fabricated or modified using ALD.

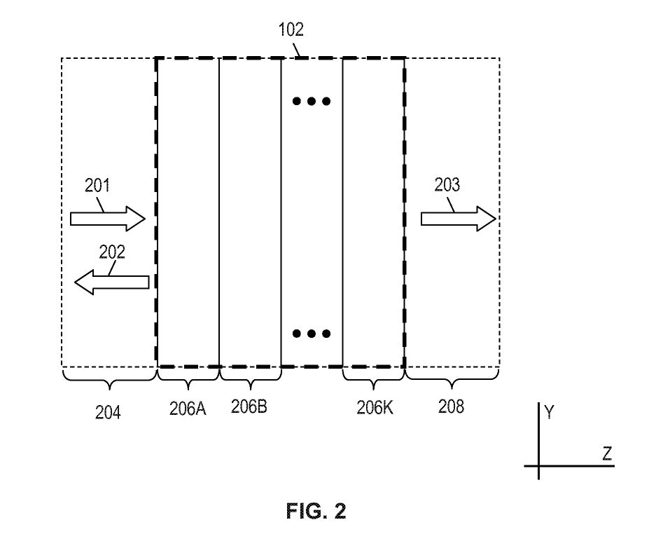

FIG. 2 shows illustrative layers 206A-206K of an ALD-based ICE such as ICE 102. At least one of the layers 206A-206K is fabricated or modified using ALD. Input medium 204 and output medium 208 are exterior layers on either side of ICE 102, and have respective indices of refraction. In some embodiments, the indices of refraction for input layer 204 and output layer 208 are equal to n₀. In alternative embodiments, the indices of refraction for input layer 204 and output layer 208 may have different values. Meanwhile, layers 206A-206K of ICE 102 may have respective indices of refraction and thicknesses.

FIG. 2 depicts incident light 201, reflected light 202, and transmitted light 203. As shown, incident light 201 enters ICE 102 from input layer 204, and travels from left to right. Reflected light 202 is reflected from the layers transitions of ICE 102, and travels from right to left. Transmitted light 203 traverses the entire body of ICE 102, and travels from left to right into output medium 208. For simplicity of illustration, ICE 102 is shown to have layers 206A-206K corresponding to materials selected for their indices of refraction among other characteristics. In various embodiments, ICE 102 may include dozens of layers, hundreds of layers, or thousands of layers.

At each layer transition of ICE 102, incident light travelling from left to right in FIG. 2 goes through a reflection/transmission process in accordance with the change in the index of refraction. Thus, a portion of the incident light is reflected and a portion is transmitted. The portion of reflected and transmitted light is governed by the principles of reflection/refraction and interference. More specifically, the electric field of incident light at a given layer transition may be denoted E⁺ᵢ(λ), the electric field of reflected light at a given layer transition may be denoted E⁻ᵢ(λ), and the electric field of transmitted light at a given layer transition may be denoted E⁺₍ᵢ₊₁₎(λ).

Reflection/refraction is governed by Fresnel laws, which for a given layer transition determine a reflectivity coefficient Rᵢ and transmission coefficient Tᵢ as:

Eᵢ⁺(λ)=Tᵢ(E⁺ᵢ₋₁(λ)), (5.1)

Eᵢ⁻(λ)=Rᵢ(Eᵢ₋₁⁺(λ)), (5.2)

Reflectivity coefficient Rᵢ and transmission coefficient Tᵢ are given by:

$$\begin{matrix}{T}_{i} = \frac{2 {n}_{i - 1}}{{n}_{i} + {n}_{i - 1}} , & ( 6.1 ) \\ {R}_{i} = \frac{{n}_{i - 1} - {n}_{i}}{{n}_{i} + {n}_{i - 1}} , & ( 6.2 )\end{matrix}$$

A negative value in Eq. (6.2) means that the reflection causes a 180 degree phase change in electric field. While more complex models can be adopted for light incident at an angle to the surface, Eqs. (5.1) and (5.2) assume normal incidence. In some embodiments, fluid analysis system 100 uses a version of Eqs. (6.1) and (6.2) including an angle of incidence of approximately 45 degrees. Eqs. (6.1), (6.2) and their generalization for different values of incidence may be found in J. D. Jackson, Classical Electrodynamics, John-Wiley & Sons, Inc., Second Edition New York, 1975, Ch. 7 Sec. 3 pp. 269-282. In general, all variables in Eqs. (5) and (6) may be complex numbers.

Note that a portion of reflected light at a given layer transition (i) travels to the left towards the previous interface (i−1). At layer transition i−1, a subsequent reflection makes that portion of reflected light travel back towards layer transition i. Thus, a portion of reflected light makes a complete cycle through a given layer and is added as a portion of transmitted light. This results in interference effects. More generally, transmitted radiation travelling from left to right in FIG. 2 may include portions reflected a number of times, P, back and forth between layer transitions of ICE 102. The number of reflections may vary. For example, a value P=0 corresponds to light that has been transmitted through ICE 102 with no reflections from left to right in FIG. 2. Thus, the transmitted light 203 will present interference effects according to the different optical paths traveled for different values of P.

Likewise, reflected light 202 travelling from right to left in FIG. 2 may include portions reflected a number of times, M, at any layer transition. Values of M may include any positive integer. Reflected light 202 will present interference effects according to the different optical paths traveled for different values of M.

Reflection and refraction are wavelength-dependent phenomena through refraction indices corresponding to layer 206A-206K. Furthermore, the optical path for field component Eᵢ^{+/-}(λ) through a given layer, i, is (2πnᵢλ)·Dᵢ. Thus, the total optical paths for different values of P depend on wavelength, index of refraction, and thickness, for each layer of ICE 102. Likewise, the total optical paths for different values of M depend on wavelength, index of refraction, and thickness, for each layer of ICE 102. Therefore, interference effects resulting in transmitted light 202_{LT} and reflected light 202_{LR} are also wavelength dependent.

For the layer transitions of ICE 102, energy conservation needs to be satisfied for each wavelength, λ. Therefore, spectral density, S_{LT}(λ) of transmitted light 202_{LT}, and spectral density S_{LR}(λ) of reflected light 202_{LR} satisfy:

Sᵢₙ(λ)=S_{LT}(λ)+S_{LR}(λ), (7)

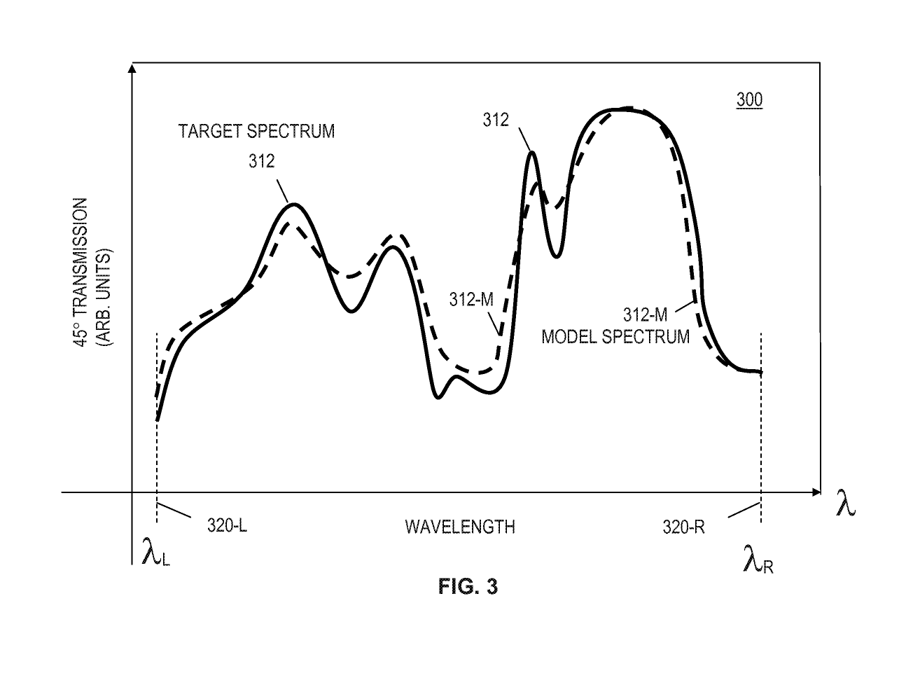

While a small portion of light may be absorbed by ICE 102 at certain wavelengths, the absorption may be negligible. In some embodiments, fluid analysis system 100 operates with ICE 102 adapted for reflection and transmission at approximately 45 degrees incidence of the incoming light. Other embodiments of fluid analysis system 100 may operate with ICE 102 adapted for any other incidence angle, such as 0 degrees, as described by Eqs. (6.1) and (6.2). Regardless of the angle of incidence for ICE 102 used in fluid analysis system 100, Eq. (7) may still express conservation of energy in any such configuration. A model of the spectral transmission and reflection characteristics of ICE 102 can be readily developed to estimate performance based on the index of refraction and thickness, for all layers involved. FIG. 3 shows target transmission spectrum 312 and intermediate model transmission spectrum 312-M for an ALD-based ICE. Also shown in FIG. 3 are left wavelength cutoff 320-L (λ_{L}), and right wavelength cutoff 320-R (λ_{R}). Cutoffs 320-L and 320-R are wavelength values that bound a wavelength range of interest for the application of fluid analysis system 100 (cf. FIG. 1). In some embodiments, it may be desired that model spectrum 312-M be approximately equal to target spectrum 312 for all wavelengths λ satisfying λ_{L}≦λ≦λ_{R}.

As shown in FIG. 3, model spectrum 312-M may be somewhat different from target spectrum 312. For example, some wavelengths inside the range of interest for model spectrum 312-M may be higher than for target spectrum 312, while other wavelengths inside the range of interest for model spectrum 312-M may be lower than for target spectrum 312. In such situations, an optimization algorithm may be employed to vary the parameters for the index of refraction and thickness sets to find values rendering a model spectrum 312-M closer to target spectrum 312. These sets define a parameter space having 2K dimensions.

In some embodiments, materials for layers 206A-206K enable the choice of 6 different indices of refraction and 1000 different thicknesses. This results in the 2K parameter space having a volume of (6*1000)^{K} possible design configurations. Therefore, optimization algorithms simplifying the optimization process may be used to scan this type of parameter space to find an optimal configuration for ICE 102.

Examples of optimization algorithms that may be used are nonlinear optimization algorithms, such as Levenberg-Marquardt algorithms. Some embodiments may use genetic algorithms to scan the parameter space and identify configurations for ICE 102 that best match target spectrum 312. Some embodiments may search a library of ICE designs to find a design for ICE 102 that most closely matches target spectrum 312. Once the design for ICE 102 is found closely matching target 412, the parameters in the 2K space may be slightly varied to find an even better model spectrum 412-M.

In some embodiments, the number of layers, K, may be included when evaluating an optimal design for ICE 102. Thus, the dimension of the parameter space may be an optimization variable according to some embodiments. Furthermore, some embodiments may include constraints for variable K. For example, some applications of system 100 may benefit from having less than a predetermined number of layers for ICE 102. In such embodiments, the fewer the number of layers the better the predictability, precision, reliability and longevity of ICE 102 and system 100. Meanwhile, other applications may benefit from having more than a predetermined number of layers for ICE 102. Regardless of the number of layers, use of ALD enables ICE design selections based on ALD tolerances as well as other fabrication features mentioned previously.

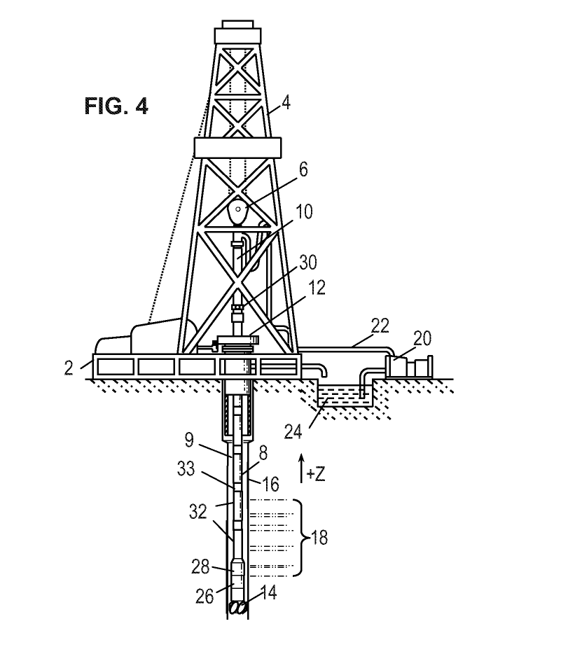

The fluid analysis system 100, where ALD is used to fabricate or modify ICE 102, BPF 106, lens 108, lens 110A, 110B, detectors 112A, 112B, and/or light source 116, may be employed in a logging while drilling (LWD) environment or a wireline logging environment to perform downhole fluid analysis operations. FIG. 4 shows an illustrative logging while drilling (LWD) environment. A drilling platform 2 supports a derrick 4 having a traveling block 6 for raising and lowering a drill string 8. A drill string kelly 10 supports the rest of the drill string 8 as it is lowered through a rotary table 12. The rotary table 12 rotates the drill string 8, thereby turning a drill bit 14. As bit 14 rotates, it creates a borehole 16 that passes through various formations 18. A pump 20 circulates drilling fluid through a feed pipe 22 to kelly 10, downhole through the interior of drill string 8, through orifices in drill bit 14, back to the surface via the annulus 9 around drill string 8, and into a retention pit 24. The drilling fluid transports cuttings from the borehole 16 into the pit 24 and aids in maintaining the integrity of the borehole 16.

The drill bit 14 is just one piece of an open-hole LWD assembly that includes one or more drill collars (thick-walled steel pipe) to provide weight and rigidity to aid the drilling process. Some of these drill collars include built-in logging instruments to gather measurements of various drilling parameters such as position, orientation, weight-on-bit, borehole diameter, etc. As an example, a logging tool 26 (such as downhole fluid analysis tool) may be integrated into the bottom-hole assembly near the bit 14. The drill string 8 may also include multiple other sections 32 that are coupled together or to other sections of the drill string 8 by adaptors 33. The logging tool 26 and/or one of sections 32 may include at least one fluid analysis system 100 as described herein.

Measurements from the tool 26 and/or sections 32 can be stored in internal memory and/or communicated to the surface. As an example, a telemetry sub 28 may be included in the bottom-hole assembly to maintain a communications link with the surface. Mud pulse telemetry is one common telemetry technique for transferring tool measurements to surface receivers 30 and receiving commands from the surface, but other telemetry techniques can also be used.

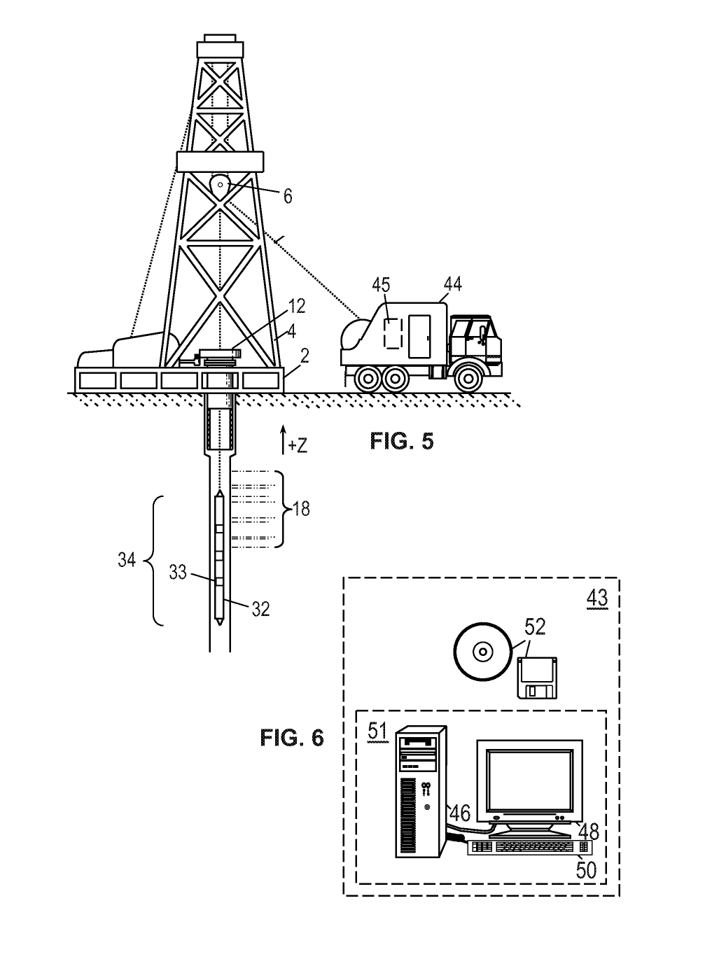

At various times during the drilling process, the drill string 8 may be removed from the borehole 16 as shown in FIG. 5. Once the drill string has been removed, logging operations can be conducted using a wireline logging tool 34, i.e., a sensing instrument sonde suspended by a cable 42 having conductors for transporting power to the tool and telemetry from the tool to the surface. It should be noted that various types of formation property sensors can be included with the wireline logging tool 34. For example, without limitation, the wireline logging tool 34 can include one or more sections 32 joined by adaptors 33. The logging tool 34 and/or one or more sections 32 may include at least one fluid analysis system 100.

A logging facility 44 collects measurements from the logging tool 34, and includes computing facilities 45 for managing logging operations and storing/processing the measurements gathered by the logging tool 34. For the logging environments of FIGS. 4 and 5, measured parameters can be recorded and displayed in the form of a log, i.e., a two-dimensional graph showing the measured parameter as a function of tool position or depth. In addition to making parameter measurements as a function of depth, some logging tools also provide parameter measurements as a function of rotational angle.

FIG. 6 shows an illustrative computer system 43 for managing logging operations. The computer system 43 may correspond to the computing facilities 45 of logging facility 44 or a remote computing system. The computer system 43 may include wired or wireless communication interfaces for managing logging operations during a logging process. As shown, the computer system 43 comprises user workstation 51, which includes a general processing system 46. The general processing system 46 is preferably configured by software, shown in FIG. 6 in the form of removable, non-transitory (i.e., non-volatile) information storage media 52, to manage logging operations including fluid analysis operations involving at least one fluid analysis system 100. The software may also be downloadable software accessed through a network (e.g., via the Internet). As shown, general processing system 46 may couple to a display device 48 and a user-input device 50 to enable a human operator to interact with system software stored by computer-readable media 52. The general processing system 46 may include surface processors and/or downhole processors. The decision to perform different processing operations at the surface or downhole may be based on preference or limitations with regard to the amount of downhole processing available, the bandwidth and data rate for data transmissions between logging tools and a surface computer, the complexity of data analysis to be performed, the durability of downhole components, or other criteria. In some embodiments, software executing on the user workstation 51 may present a logging management interface with fluid analysis options to the user. Stated in another fashion, various logging management methods described herein can be implemented in the form of software that can be communicated to a computer or another processing system on an information storage medium such as an optical disk, a magnetic disk, a flash memory, or other persistent storage device. Alternatively, such software may be communicated to the computer or processing system via a network or other information transport medium. The software may be provided in various forms, including interpretable “source code” form and executable “compiled” form. The various operations carried out by the software as described herein may be written as individual functional modules (e.g., “objects”, functions, or subroutines) within the source code.

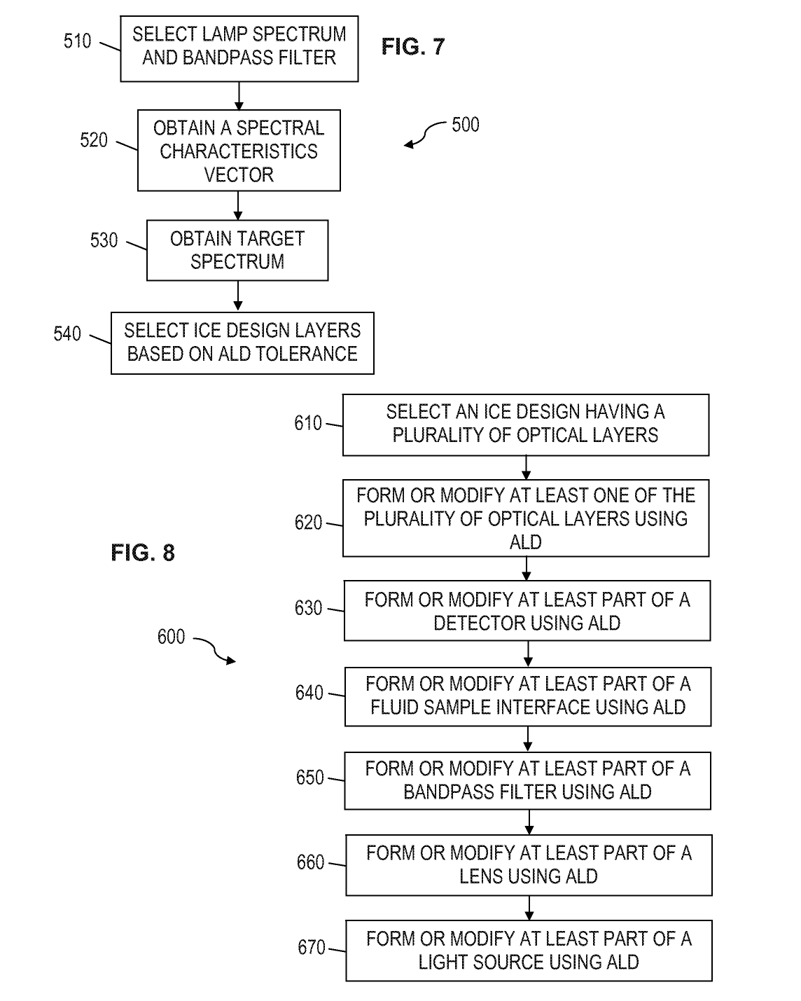

FIG. 7 shows a flowchart illustrating an ICE fabrication method 500. As shown, method 500 comprises selecting a lamp spectrum and bandpass filter at block 510. At block 520, a spectral characteristics vector is obtained. For example, the spectral characteristics vector may be approximately equal to a regression vector solving a linear multivariate problem. At block 530, a target spectrum is obtained. The target spectrum is obtained from the lamp spectrum, the bandpass filter spectrum, and the spectral characteristics vector. At block 540, ICE design layers are selected based on ALD tolerances. The layers selected may be based on an optimization routine that varies the index of refraction, the thickness, and the number of layers in a parameter space until an error between a model spectrum and a target spectrum is less than a tolerance value. In some embodiments, the optimization routine may be a nonlinear routine such as a Levenberg-Marquardt routine or generic algorithm. Use of ALD to fabricate or modify ICE layers enables ICE design options to be selected that are within ALD tolerance levels, but not reactive magnetic sputtering tolerance (RMS) levels. In some embodiments, a combination of ALD and RMS may be employed (e.g., some layers are fabricated using RMS while others are fabricated using ALD).

FIG. 8 shows a flowchart illustrating a fluid analysis system fabrication method 600. In method 600, various optical path components of a fluid analysis system are formed using ALD. At block 610, an ICE design having a plurality of optical layers is selected. At block 620, at least one of the plurality of optical layers is formed or modified using ALD. At block 630, at least part of a detector is formed or modified using ALD. At block 640, at least part of a fluid sample interface is formed or modified using ALD. At block 650, at least part of a bandpass filter is formed or modified using ALD. At block 660, at least part of a lens is formed or modified used ALD. The various ALD-based components mentioned in method 600 may be arranged, for example, as described for system 100 of FIG. 1. At block 670, at least part of a light source is formed or modified used ALD. The various ALD-based components mentioned in method 600 may be arranged, for example, as described for system 100 of FIG. 1. Different fluid analysis systems may have fewer or additional ALD-based components, and method 600 would vary accordingly. Further, different components of a fluid analysis system may have layers formed using only ALD, only RMS, or both. There are various known ALD techniques, which may be employed to form optical path components of a fluid analysis system as in method 600. Generally, ALD is a film growth technique that uses pairs of self limiting chemical reactions carried out in near vacuum conditions. The surfaces of the substrates are covered in a monolayer with the first reactant, the vacuum is used to purge the system and the second reactant is introduced into the system. The second reactant contacts the substrate with the monolayer and reacts forming a completed layer for an ICE or other optical path component. There are many commercial pairs of reactants available. The cycle can be repeated until the desired layer thickness has been achieved. For example, the layer control mechanism may count the number of reagent additions. Reaction times are quick and growth rates as high as 100 angstroms in 40 minutes are possible. ALD has been used to grow films, e.g., Al₂O₃, with desirable optical properties and with hardness properties suitable for extreme applications. For ICE fabrication, films of alternating high and low optical refractive indices may be grown. High index materials such as silicon and germanium, and low index materials such as SiO₂ and MgO₂ have been used to grow ALD films.

With ALD, the quality assurance, quality control, and yield may be higher and more easily controlled. As an example, the quality control for ALD may involve a straightforward process of counting reactant additions, and then checking for performance. The monitoring of the ALD process may be performed in real-time via with optical instruments to confirm layering depth and other fabrication criteria. Further, ALD is a chemical reaction process that results in a chemical bond to the base surface. Thus, the bond formed by ALD is stronger (less delicate) than the bond formed by other deposition processes such as magnetron sputtering or plasma coating processes.

As disclosed herein, ALD may be employed to fabricate more complex ICE designs with thinner overall thickness (which results in faster fabrication times and better performance than existing deposition techniques). Further, ALD may be used to fabricate functionalized ICEs. For example, a terminating layer may be designed to have one or more chemically reactive layers, bonded directed to the ICE. This would enable ICEs to be more selective for an analyte or group of analytes than before. As another example, a terminating layer may be designed to be a protective coating of different material than used to design the spectral profile of the ICE. As another example, the surface can be patterned to enable use as a size-exclusion layer in an environment where the medium is highly light scattering (e.g., reservoir fluids). Such patterning can be performed with strippable resist techniques. In a well mixed environment, all surfaces may be coated and substrates may be bonded face to face. Use of ALD also may enable performance or functionality improvements to other optical path components of a fluid analysis system.

Besides ICE 102, other optical components of system 100 can be fabricated or modified by ALD. For example, semiconductor detectors may be fabricated by ALD or modified by ALD to include the ICE 102 directly on the surface. Further, semiconductor detectors may be modified to include an anti-reflection or spectral bandpass layer structure. As another example, lenses 110A and 110B can be modified to include an anti-reflection or spectral bandpass layer structure.

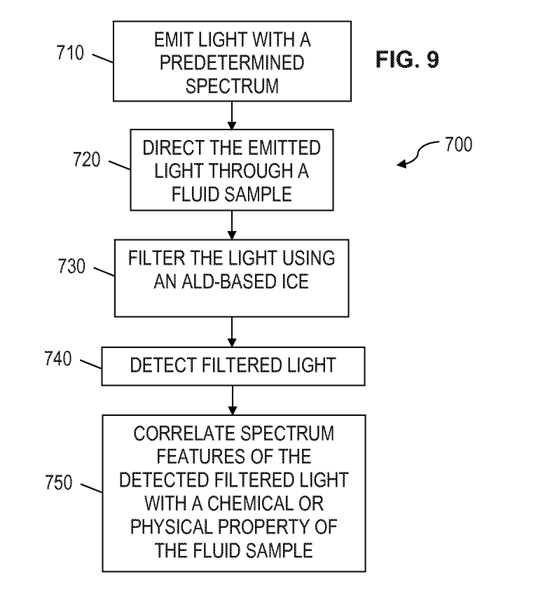

FIG. 9 shows a flowchart of an illustrative fluid analysis method 700. As shown, the method 700 includes emitting light (e.g., with light source 116) with a predetermined spectrum at block 710. At block 720, the emitted light is directed through a fluid sample (e.g., fluid sample 104). At block 730, light that passed through the fluid sample is filtered using an ALD-based ICE (e.g., ICE 102). As described herein, an ALD-based ICE includes a plurality of optical layers, where at least one of the layers is formed or modified using ALD. The use of ALD for one or more optical layers of an ICE can increase the accuracy, types, and/or range of predictions made by a fluid analysis system At block 740, filtered light is detected (e.g., by detectors 112A or 112B). At block 750, spectrum features of the detected filtered light are correlated with a chemical or physical property of the fluid sample. The step of block 750 may be performed, for example, by a processor coupled to detectors of a fluid analysis system.

In some embodiments, the method 700 may include additional steps. For example, the method 700 may also include, before and/or after the filtering step, directing light through at least one optical path component formed or modified using ALD. Such optical path components may include input-side lenses, output-side lenses, bandpass filters, sample interfaces, light sources, or detectors as described herein.

Numerous variations and modifications will become apparent to those skilled in the art once the above disclosure is fully appreciated. For example, though the methods disclosed herein have been shown and described in a sequential fashion, at least some of the various illustrated operations may occur concurrently or in a different sequence, with possible repetition. It is intended that the following claims be interpreted to embrace all such variations, equivalents, and modifications.

1. A fluid analysis system, comprising:
a light source;
an integrated computation element (ICE); and
a detector that converts optical signals to electrical signals,
wherein the ICE comprises a plurality of optical layers, and wherein at least one of the plurality of optical layers is formed using atomic layer deposition (ALD) to enable prediction of a chemical or physical property of a substance.

2. The fluid analysis system of claim 1, wherein the ICE comprises a plurality of different types of optical layers based on ALD, and wherein the plurality of different types of optical layers have different indices of refraction.

3. The fluid analysis system of claim 1, wherein the ICE comprises at least one optical layer formed using reactive magnetic sputtering (RMS).

4. The fluid analysis system of claim 1, wherein the ICE comprises at least one non-planar optical layer formed or modified using ALD.

5. The fluid analysis system according to any of claim 1, further comprising a fluid sample interface, wherein the fluid sample interface comprises at least one layer formed or modified using ALD.

6. The fluid analysis system of claim 5, wherein the fluid sample interface comprises a diamond layer formed using ALD.

7. The fluid analysis system of claim 1, wherein the detector or the light source comprises at least one layer formed or modified using ALD.

8. The fluid analysis system of claim 1, further comprising a bandpass filter element, wherein the bandpass filter element comprises at least one layer formed or modified using ALD.

9. The fluid analysis system of claim 1, further comprising an input-side lens with respect to the ICE, wherein the input-side lens comprises at least one layer formed or modified using ALD.

10. The fluid analysis system of claim 1, further comprising an output-side lens with respect to the ICE, wherein the output-side lens comprises at least one layer formed or modified using ALD.

11. A method for fabricating a fluid analysis system, comprising:
selecting an integrated computation element (ICE) design having a plurality of optical layers; and
forming at least one of the plurality of optical layers of the ICE using atomic layer deposition (ALD) to enable prediction of a chemical or physical property of a substance.

12. The method of claim 11, further comprising forming or modifying at least part of a light source or detector using ALD.

13. The method of claim 11, further comprising forming or modifying at least part of a fluid sample interface using ALD and arranging the fluid sample interface at an input-side of the ICE.

14. The method of claim 11, further comprising forming or modifying at least part of a bandpass filter element using ALD and arranging the bandpass filter element at an input-side of the ICE.

15. The method of claim 11, further comprising forming or modifying at least part of a lens using ALD and arranging the lens at an input-side or output-side of the ICE.

16. The method of claim 11, further comprising forming or modifying at least one non-planar optical layer of the ICE using ALD.

17. The method of claim 11, further comprising forming a plurality of different types of optical layers of the ICE using ALD.

18. A logging string, comprising:
a logging tool section; and
a fluid analysis tool associated with the logging tool section, wherein the fluid analysis tool comprises an integrated computation element (ICE) with at least one optical layer formed using atomic layer deposition (ALD) to enable prediction of a chemical or physical property of a substance.

19. The logging string of claim 18, wherein the fluid analysis unit comprises at least one of a detector a bandpass filter formed or modified using ALD.

20. A method for fluid analysis, comprising:
directing light having a predetermined spectrum through a fluid sample;
filtering light output from the fluid sample though a plurality of optical layers, wherein at least one of the plurality of optical layers is formed using atomic layer deposition (ALD) to filter the light in dependence on a chemical or physical property in the fluid sample;
detecting filtered light output from the plurality of optical layers; and
correlating spectrum features of the filtered light to said chemical or physical property of the fluid sample.

21. The method of claim 20, further comprising, before said filtering, directing light through at least one optical path component formed or modified using ALD.

22. The method of claim 20, further comprising, after said filtering and before said detecting, directing light through at least one optical path component formed or modified using ALD.
